(19) United States
(12) Patent Application Publication
(10) Pub. No.: US 2023/0140458 A1
(43) Pub. Date: May 4, 2023

(54) MEASUREMENT APPARATUS

(71) Applicant: FUJIFILM Business Innovation Corp., Tokyo (JP)

(72) Inventors: Junichiro HAYAKAWA, Kanagawa (JP); Yoshiyuki SUZUKI, Kanagawa (JP)

(73) Assignee: FUJIFILM Business Innovation Corp., Tokyo (JP)

(21) Appl. No.: 17/714,162

(22) Filed: Apr. 6, 2022

(30) Foreign Application Priority Data
Nov. 2, 2021 (JP) 2021-179309

(51) Int. Cl. H01S 5/0683; H01S 5/02

(52) U.S. Cl. CPC H01S 5/0683; H01S 5/021

(57) ABSTRACT

A measurement apparatus includes a light emitter including a substrate and a light emission unit that emits light in an inclined direction inclined with respect to the substrate and a normal line of the substrate, and a light receiver that receives, on a light reception surface, reflected light emitted from the light emitter and reflected by an object to be measured, in which in a case where an angle formed by the light emitted from the light emitter and the substrate of the light emitter is an angle θ1 (0°<θl<90°), an angle θ2 formed by the substrate and the light reception surface of the light receiver satisfies 0°<θ2<180°−2θ1.

### CROSS-REFERENCE TO RELATED APPLICATIONS

This application is based on and claims priority under 35 USC 119 from Japanese Patent Application No. 2021-179309 filed Nov. 2, 2021.

### BACKGROUND

### (i) Technical Field

The present invention relates to a measurement apparatus.

### (ii) Related Art

As a related art, JP2020-136655A discloses a semiconductor light amplifier including a light source unit that emits laser light and a light amplification unit that includes an active region formed on a substrate and formed in an extended manner from the light source unit in a direction set in advance along a surface of the substrate, amplifies propagation light propagating from the light source unit in the direction set in advance, and emits the amplified propagation light in a direction intersecting the substrate surface.

### SUMMARY

In a case where a light emitter including a light emission unit that emits light in an oblique direction inclined with respect to the substrate and a normal line of the substrate emits light to an object and a light receiver receives reflected light reflected by the object to be measured, the reflected light may be difficult to be received by the light receiver depending on an orientation of the substrate of the light emitter.

Aspects of non-limiting embodiments of the present disclosure relate to a measurement apparatus that enables a light receiver to easily receive reflected light in a case where a light emitter that emits light in an oblique direction emits light to an object to be measured and the light receiver receives the reflected light reflected by the object to be measured, as compared with a case where a substrate of the light emitter is parallel to a light reception surface of the light receiver.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a measurement apparatus including a light emitter including a substrate and a light emission unit that emits light in an inclined direction inclined with respect to the substrate and a normal line of the substrate, and a light receiver that receives, on a light reception surface, reflected light emitted from the light emitter and reflected by an object to be measured, in which in a case where an angle formed by the light emitted from the light emitter and the substrate of the light emitter is an angle θ1 (0°<θ1<90°), an angle θ2 formed by the substrate and the light reception surface of the light receiver satisfies 0°<θ2<180°−2ƒ1.

### BRIEF DESCRIPTION OF THE DRAWINGS

Exemplary embodiment(s) of the present invention will be described in detail based on the following figures, wherein:

FIG. 1 is a diagram showing an example of a configuration of a distance measurement apparatus to which a first exemplary embodiment is applied;

FIG. 2 is a view of the distance measurement apparatus shown in FIG. 1 as viewed from a II direction;

FIG. 3 is a plan view of a semiconductor multilayer structure to which the present exemplary embodiment is applied;

FIG. 4 is a cross-sectional view taken along a line IV-IV shown in FIG. 3;

FIG. 5 is a diagram showing an example of a configuration of a distance measurement apparatus different from the distance measurement apparatus according to the present exemplary embodiment;

FIG. 6 is a diagram showing an example of a configuration of a distance measurement apparatus to which a second exemplary embodiment is applied;

FIG. 7 is a diagram showing a modification example of the distance measurement apparatus to which the second exemplary embodiment is applied;

FIG. 8 is a diagram for describing an optical path length and the like until light emitted from a semiconductor multilayer structure reaches an object to be measured in the distance measurement apparatus;

FIG. 9 is a diagram for describing a configuration of a distance measurement apparatus to which a third exemplary embodiment is applied and is a diagram showing a configuration between a light emitter and the object to be measured;

FIG. 10 is a diagram showing an example of a configuration of a distance measurement apparatus to which a fourth exemplary embodiment is applied;

FIG. 11 is a diagram showing a modification example of the distance measurement apparatus to which the fourth exemplary embodiment is applied;

FIG. 12 is a plan view of a semiconductor multilayer structure to which a fifth exemplary embodiment is applied; and

FIG. 13 is a cross-sectional view taken along a line XIII-XIII shown in FIG. 12.

### DETAILED DESCRIPTION

### First Exemplary Embodiment

Distance Measurement Apparatus 1

Hereinafter, exemplary embodiments of the present invention will be described in detail with reference to the drawings.

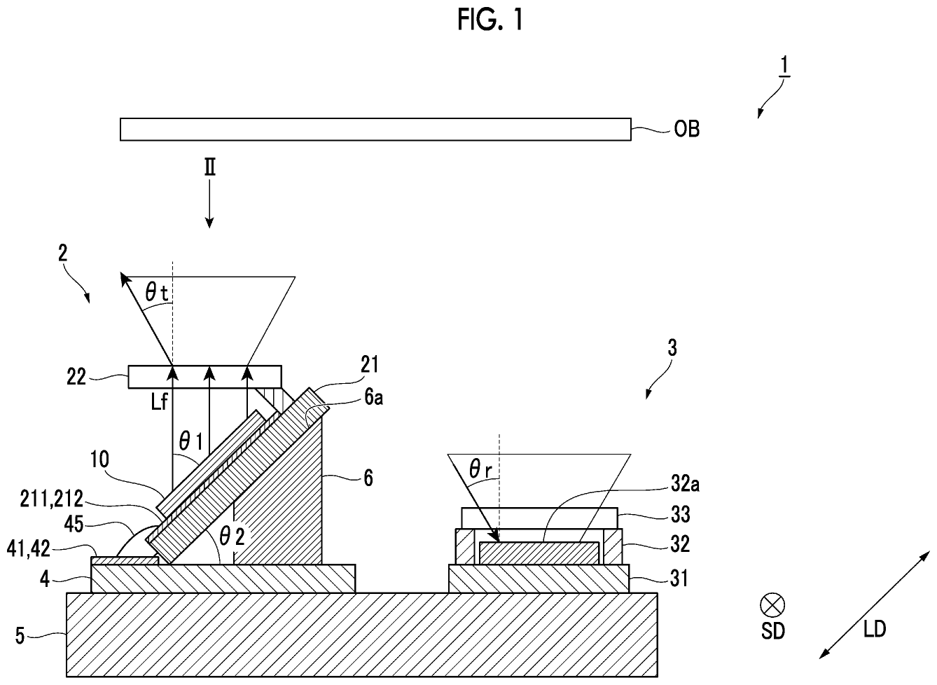

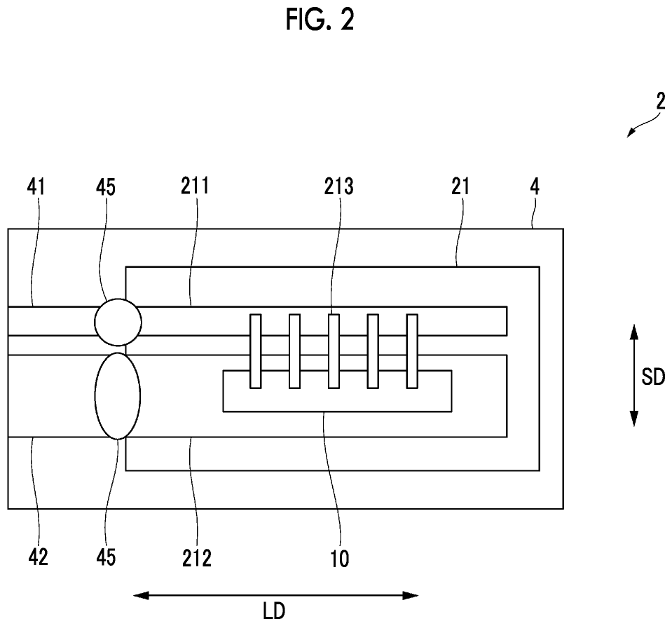

FIG. 1 is a diagram showing an example of a configuration of a distance measurement apparatus 1 to which a first exemplary embodiment is applied. FIG. 2 is a view of the distance measurement apparatus 1 shown in FIG. 1 as viewed from a II direction.

The distance measurement apparatus 1 according to the present exemplary embodiment is used to measure a distance between the distance measurement apparatus 1, which is an example of a measurement apparatus, and an object to be measured OB disposed via a gap with respect to the distance measurement apparatus 1. As shown in FIG. 1, the distance measurement apparatus 1 includes a light emitter 2 that emits light and a light receiver 3 that receives reflected light emitted from the light emitter 2 and reflected by the object to be measured OB. Further, the distance measurement apparatus 1 includes a PCB board 4 on which wiring for supplying electric power to the light emitter 2 and the like is formed, and a pedestal 5 that supports the light emitter 2, the light receiver 3, and the PCB board 4. Furthermore, the distance measurement apparatus 1 includes an angle adjustment member 6 that adjusts an angle of the light emitter 2 with respect to the light receiver 3.

Light Emitter 2

As shown in FIG. 1, the light emitter 2 includes a semiconductor multilayer structure 10 that emits the light, an emission-side substrate 21 on which the semiconductor multilayer structure 10 is loaded (hereinafter simply referred to as a substrate 21), and a diffusion plate 22 that is provided between the semiconductor multilayer structure 10 and the object to be measured OB and diffuses and transmits the light emitted from the semiconductor multilayer structure 10 toward the object to be measured OB.

Semiconductor Multilayer Structure 10

The semiconductor multilayer structure 10 is an example of a light emission unit and emits the light in an oblique direction inclined with respect to the substrate 21 having a flat plate shape and a normal line of the substrate 21. The normal line of the substrate 21 means a line extending in a perpendicular direction from a surface, in the substrate 21 having a flat plate shape, on which the semiconductor multilayer structure 10 is loaded.

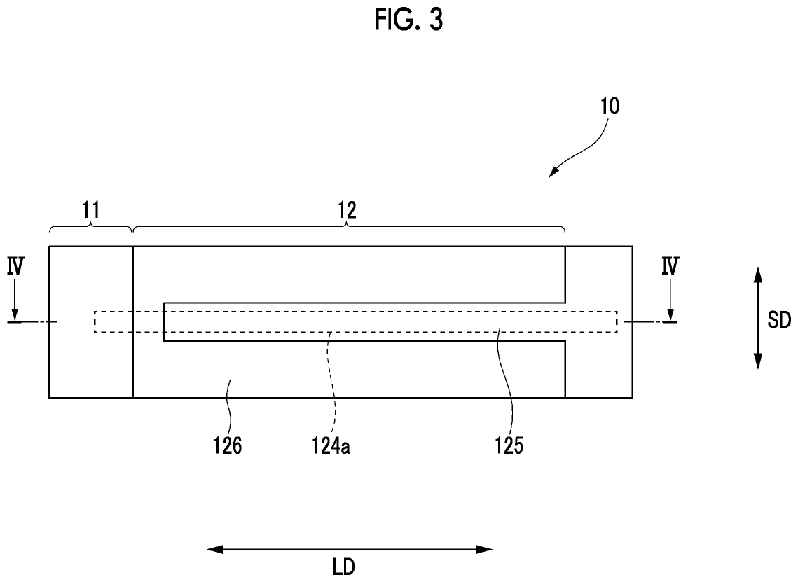

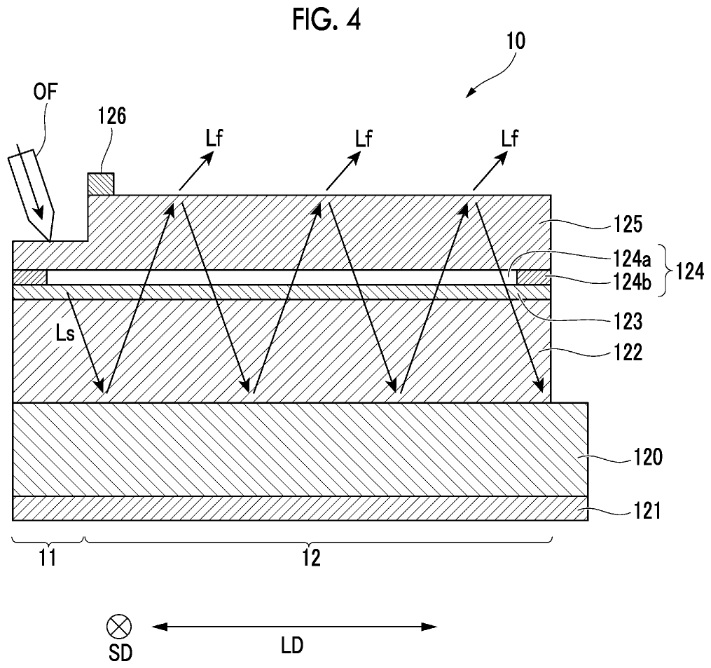

FIG. 3 is a plan view of the semiconductor multilayer structure 10 to which the present exemplary embodiment is applied, and FIG. 4 is a cross-sectional view taken along a line IV-IV shown in FIG. 3. As shown in FIG. 3, the semiconductor multilayer structure 10 has a longitudinal direction LD and a lateral direction SD orthogonal to the longitudinal direction LD, and includes an optical coupling portion 11 provided at one end in the longitudinal direction LD and a light amplification unit 12 extending from the optical coupling portion 11 along the longitudinal direction LD.

The optical coupling portion 11 couples a light source that generates seed light Ls, which is input light to the semiconductor multilayer structure 10. In the semiconductor multilayer structure 10 according to the present exemplary embodiment, the input light is propagated from an external light source (not shown) via an optical fiber OF, and an output end of the optical fiber OF is coupled to the optical coupling portion 11 to introduce the input light to the light amplification unit 12. For example, a vertical cavity surface emitting laser (VCSEL) is used as the external light source. A lensed fiber may be used as the optical fiber OF from the viewpoint of light coupling efficiency.

The light amplification unit 12 has a function of amplifying and emitting the seed light Ls coupled to the optical coupling portion 11. The light amplification unit 12 according to the present exemplary embodiment is a surface-emission light amplification unit using a distributed Bragg reflector waveguide (hereinafter referred to as a DBR waveguide) having a GaAs diameter as an example. Specifically, the light amplification unit 12 includes an N electrode 121 stacked on one surface (back surface) of a base layer 120. The light amplification unit 12 includes a lower DBR layer 122, an active layer 123, an oxidization constriction layer 124, an upper DBR layer 125, and a P electrode 126, which are sequentially stacked on the other surface (front surface) of the base layer 120.

In the present exemplary embodiment, the base layer 120 is an n-type GaAs substrate, and an N electrode 121 that is in ohmic contact with the n-type GaAs substrate is provided on the back surface of the base layer 120.

The lower DBR layer 122 is n-type, and the upper DBR layer 125 is p-type. In a case where the semiconductor multilayer structure 10 is driven, a positive electrode of a driving power source is applied to the P electrode 126 and a negative electrode thereof is applied to the N electrode 121 to cause a drive current to flow from the P electrode 126 to the N electrode 121. However, the polarities of the base layer 120, the lower DBR layer 122, and the upper DBR layer 125 are not limited thereto. The polarities may be reversed, that is, the base layer 120 may be a p-type GaAs substrate, the lower DBR layer 122 may be a p-type, and the upper DBR layer 125 may be an n-type.

The lower DBR layer 122 is paired with the upper DBR layer 125 described below to form a resonator that contributes to light emitting in the semiconductor multilayer structure 10. The lower DBR layer 122 is a multilayer film reflector configured by alternately and repeatedly stacking two semiconductor layers having a thickness of 0.25 λ/n each and different refractive indexes in a case where an oscillation wavelength of the semiconductor multilayer structure 10 is λ and a refractive index of a medium (semiconductor layer) is n. As a specific example, the lower DBR layer 122 is configured by alternately and repeatedly stacking an n-type low refractive index layer made of Al_{0.9}Ga_{0.1}As and an n-type high refractive index layer made of Al_{0.2}Ga_{0.8}As.

The active layer 123 according to the present exemplary embodiment may be configured to include, for example, a lower spacer layer, a quantum well active region, and an upper spacer layer, which are not shown. The quantum well active region according to the present exemplary embodiment may be configured of, for example, barrier layers consist of four layers of Al_{0.3}Ga_{0.7}As and quantum well layers consist of three layers of GaAs provided between the barrier layers. The lower spacer layer and the upper spacer layer are respectively disposed between the quantum well active region and the lower DBR layer 122 and between the quantum well active region and the upper DBR layer 125 to have a function of adjusting a length of the resonator and a function as a clad layer to confine a carrier.

The oxidization constriction layer 124 provided on the active layer 123 includes a non-oxidized region 124a and an oxidized region 124b. The oxidized region 124b is a region where a current does not easily flow, and the non-oxidized region 124a is a region where a current easily flows. That is, the oxidization constriction layer 124 constricts a path through which the current flows in the semiconductor multilayer structure 10.

In the present exemplary embodiment, the oxidization constriction layer 124 is composed of one layer on a base layer 120 side among multilayer films constituting the upper DBR layer 125 described below. That is, with oxidization of a part of the one layer constituting the upper DBR layer 125, the oxidized region 124b is formed, and an unoxidized region other than the oxidized region 124b becomes the non-oxidized region 124a. In the present exemplary embodiment, the oxidization constriction layer 124 is formed in one layer of the upper DBR layer 125 has been described as an example, but the present invention is not limited thereto. The oxidization constriction layer 124 may be formed into a plurality of layers of the upper DBR layer 125 or in the lower DBR layer 122.

The upper DBR layer 125 is a multilayer film reflector configured by alternately and repeatedly stacking two semiconductor layers having a film thickness of 0.25 λ/n each and having different refractive indexes. As a specific example, the upper DBR layer 125 is configured by alternately and repeatedly stacking an n-type low refractive index layer made of Al_{0.9}Ga_{0.1}As and an n-type high refractive index layer made of Al_{0.2}Ga_{0.8}As.

The light amplification unit 12 according to the present exemplary embodiment, which is a DBR waveguide, will be described in more detail. The seed light Ls introduced from the optical coupling portion 11 propagates, in the light amplification unit 12, in a propagation direction (longitudinal direction LD of the semiconductor multilayer structure 10) from a left side to a right side of a paper surface of FIGS. 3 and 4. In this case, the propagation light propagates mostly in the lower DBR layer 122, the active layer 123, the non-oxidized region 124a of the oxidization constriction layer 124, and the upper DBR layer 125 with a distribution set in advance, as shown in FIG. 4. Therefore, the “DBR waveguide” is configured to include the above parts.

The semiconductor multilayer structure 10 using the light amplification unit 12 which is the DBR waveguide is configured of a pair of DBRs (lower DBR layer 122 and upper DBR layer 125), which is provided on the base layer 120, and the active layer 123 and the oxidization constriction layer 124 between the pair of DBRs. A region sandwiched between the DBRs functions as an optical waveguide, and the light input into the optical waveguide propagates in a slow light mode while being multiple-reflected in an oblique direction. In this case, in a case where a current is injected into the active layer 123 by the P electrode 126 and the N electrode 121 provided on both sides of the DBR waveguide, the input light is amplified. The amplified light is output in a direction that intersects the base layer 120 and a normal line of the base layer 120 and is inclined forward in the propagation direction (longitudinal direction LD) of the propagation light in the light amplification unit 12. In FIG. 4 and FIG. 1 described above, the light output from the light amplification unit 12 and emitted to the outside from the semiconductor multilayer structure 10 is shown as emission light Lf.

That is, the light amplification unit 12, which is a region (region sandwiched between the P electrode 126 and the N electrode 121) where the P electrode 126 and the N electrode 121 are provided in the semiconductor multilayer structure 10, has a function of propagating the light and a function of amplifying the light. The light amplified by the light amplification unit 12 of the semiconductor multilayer structure 10 is emitted, as the emission light Lf, in the direction intersecting the base layer 120 and the normal line of the base layer 120.

For the light input to the light amplification unit 12, a part of the DBR is removed by etching to create a light incident portion (optical coupling portion 11) having a reduced reflectance and external light is obliquely incident for coupling. Further, for the light input to the light amplification unit 12, although the details will be described below, a light source (seed light unit) is laterally integrated as a part of the semiconductor multilayer structure 10 and light exuded to the light amplification unit 12 may be propagated.

Substrate 21

Returning to FIGS. 1 and 2, the semiconductor multilayer structure 10 is loaded on one surface (upper surface in FIG. 1) of the substrate 21 of the light emitter 2.

The substrate 21 is formed with wiring for supplying electric power to the semiconductor multilayer structure 10. Specifically, the substrate 21 is formed with anode wiring 211 connected to the P electrode 126 (refer to FIG. 4) in the semiconductor multilayer structure 10 and cathode wiring 212 connected to the N electrode 121 (refer to FIG. 4) in the semiconductor multilayer structure 10 A, as shown in FIG. 2. In this example, the anode wiring 211 of the substrate 21 and the P electrode 126 of the semiconductor multilayer structure 10 are connected via a plurality of bonding wires 213. The cathode wiring 212 of the substrate 21 and the N electrode 121 of the semiconductor multilayer structure 10 are connected with the loading of the semiconductor multilayer structure 10 on the cathode wiring 212 of the substrate 21.

As described above, the semiconductor multilayer structure 10 loaded on the substrate 21 emits the emission light Lf in the direction intersecting the base layer 120 and the normal line of the base layer 120. Therefore, in the light emitter 2 according to the present exemplary embodiment, the semiconductor multilayer structure 10 emits the emission light Lf in the oblique direction inclined with respect to the substrate 21 and the normal line of the substrate 21. In the following, an angle formed by the substrate 21 and the emission light Lf in a cross section of the semiconductor multilayer structure 10 perpendicular to the lateral direction SD may be referred to as an emission angle θ1.

The emission angle θ1 satisfies 0<θ1<90°. The emission angle θ1 varies depending on the configuration of the semiconductor multilayer structure 10 and the like, but is, for example, preferably 30°<θ1<60°.

Diffusion Plate 22

The diffusion plate 22 of the light emitter 2 diffuses the emission light Lf emitted from the semiconductor multilayer structure 10 at a diffusion angle θt set in advance and transmits the emission light toward the object to be measured OB. The diffusion angle θt is an angle at which the light transmitted through the diffusion plate 22 diffuses with respect to an optical axis direction of the light incident on the diffusion plate 22.

The diffusion plate 22 is supported at an angle set in advance with respect to the semiconductor multilayer structure 10 such that the emission light Lf emitted from the semiconductor multilayer structure 10 is perpendicularly incident.

Light Receiver 3

The light receiver 3 includes a light-receiving side substrate 31 loaded on the pedestal 5, a light reception sensor 32 that is loaded on the light-receiving side substrate 31, receives the reflected light from the object to be measured, and outputs an electric signal, and a filter 33 that is provided between the light reception sensor 32 and the object to be measured and transmits the light having a wavelength set in advance.

The light reception sensor 32 receives the light (reflected light) reflected by the object to be measured OB and transmitted through the filter 33 on a light reception surface 32a, and outputs the electric signal according to an amount of light received. The light reception sensor 32 is composed of, for example, a photodiode or a phototransistor. The electric signal from the light reception sensor 32 is output to a calculation unit (not shown) composed of a central processing unit (CPU), an application specific integrated circuit (ASIC), or the like. The calculation unit performs calculation processing set in advance on the electric signal from the light reception sensor 32 to calculate the distance between the distance measurement apparatus 1 and the object to be measured OB.

In this example, the light reception sensor 32 is horizontally disposed along a left-right direction in the figure such that the light reception surface 32a faces the object to be measured OB, as shown in FIG. 1. The light reception sensor 32 can receive light within a range of a light-receiving viewing angle θr set in advance with respect to a normal line of the light reception surface 32a.

PCB Board 4

Wiring connected to the wiring formed on the substrate 21 of the light emitter 2 is formed on the PCB board 4. Specifically, anode wiring 41 connected to the anode wiring 211 of the substrate 21 and cathode wiring 42 connected to the cathode wiring 212 of the substrate 21 are formed on the PCB board 4. In this example, the anode wiring 211 of the substrate 21 is connected to the anode wiring 41 of the PCB board 4 by a solder 45. Similarly, the cathode wiring 212 of the substrate 21 is connected to the cathode wiring 42 of the PCB board 4 by the solder 45. Further, the anode wiring 41 and the cathode wiring 42 of the PCB board 4 are connected to a power supply (not shown).

Accordingly, in the distance measurement apparatus 1 according to the present exemplary embodiment, the electric power is supplied to the semiconductor multilayer structure 10 of the light emitter 2 via the anode wiring 41 and the cathode wiring 42 formed on the PCB board 4 and the anode wiring 211 and the cathode wiring 212 formed on the substrate 21.

Pedestal 5

The pedestal 5 collectively supports the light emitter 2, the light receiver 3, the PCB board 4, and the angle adjustment member 6. In addition, the pedestal 5 supports the light emitter 2 and the light receiver 3 such that a distance between the light emitter 2 and the light receiver 3 is a distance set in advance.

Angle Adjustment Member 6

The angle adjustment member 6 is a member that supports the substrate 21 of the light emitter 2 and adjusts the substrate 21 and the light reception surface 32a in the light reception sensor 32 of the light receiver 3 to have an angle set in advance.

The angle adjustment member 6 has a cross-sectional shape similar to the shape shown in FIG. 1 from one end to the other end in the lateral direction SD of the semiconductor multilayer structure 10. As shown in FIG. 1, the angle adjustment member 6 has an inclined surface 6a forming an angle set in advance with respect to the light reception surface 32a in the light reception sensor 32. In the distance measurement apparatus 1 according to the present exemplary embodiment, the substrate 21 is loaded on the inclined surface 6a of the angle adjustment member 6, and thus the substrate 21 and the light reception surface 32a in the light reception sensor 32 of the light receiver 3 have the angle set in advance. Hereinafter, the angle formed by the substrate 21 of the light emitter 2 and the light reception surface 32a in the light reception sensor 32 of the light receiver 3 is referred to as a substrate angle θ2. The substrate angle θ2 will be described below in detail.

By the way, in a case where the light emitter 2 including the semiconductor multilayer structure 10 that emits the light in the oblique direction inclined with respect to the substrate 21 and the normal line of the substrate 21 emits the light to the object to be measured OB and the light receiver 3 receives the reflected light reflected by the object to be measured is OB, the reflected light may be difficult to be received by the light receiver 3 depending on an orientation of the substrate 21 of the light emitter 2.

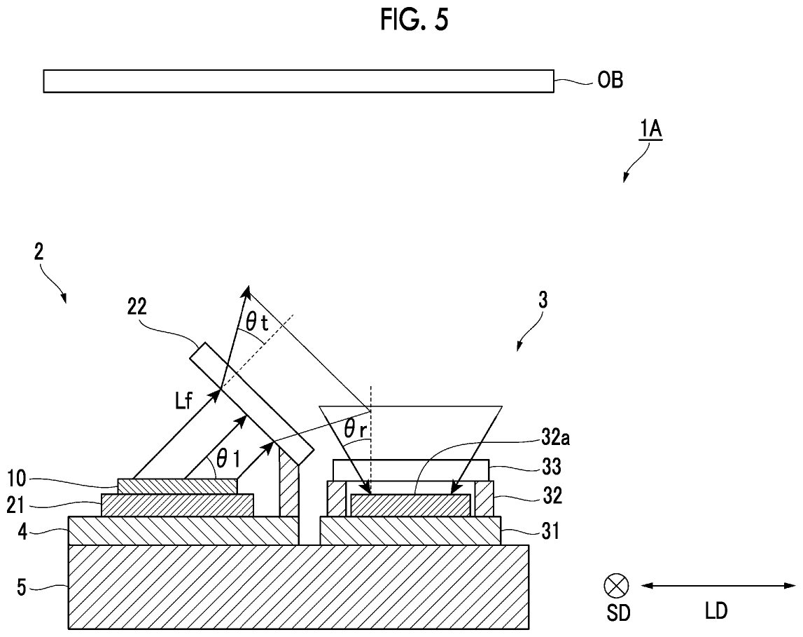

FIG. 5 is a diagram showing an example of a configuration of a distance measurement apparatus (hereinafter referred to as a distance measurement apparatus LA) different from the distance measurement apparatus 1 according to the present exemplary embodiment. In FIG. 5, the same reference numerals are used for the same configurations as the configurations of the distance measurement apparatus 1 according to the present exemplary embodiment shown in FIGS. 1 and 2.

In the distance measurement apparatus 1A shown in FIG. 5, the light emitter 2 and the light receiver 3 are disposed on the pedestal 5 such that the substrate 21 of the light emitter 2 is parallel to the light reception surface 32a in the light reception sensor 32 of the light receiver 3. In a case where the substrate 21 is parallel to the light reception surface 32a, for the reflected light emitted from the semiconductor multilayer structure 10 of the light emitter 2 and reflected by the object to be measured OB, an angle formed with the light reception surface 32a tends to be smaller than the light-receiving viewing angle θr in the distance measurement apparatus LA. In this case, the reflected light from the object to be measured OB is difficult to be received by the light reception sensor 32.

In the distance measurement apparatus 1A shown in FIG. 5, in order to enable the light reception sensor 32 of the light receiver 3 to easily receive the reflected light emitted from the light emitter 2 and reflected by the object to be measured OB, the light-receiving viewing angle θr of the light reception sensor 32 is, for example, preferably made larger by the emission angle θ1 than the diffusion angle θt of the diffusion plate 22 in the light emitter 2. However, in a case where the light-receiving viewing angle θr of the light reception sensor 32 is increased, the light reception sensor 32 easily receives the reflected light. However, a range that does not contribute to the reception of the reflected light of a range within the light-receiving viewing angle θr in the light reception sensor 32 is widened, and waste tends to increase.

On the contrary, in the distance measurement apparatus 1 according to the present exemplary embodiment, the angle of the light emitter 2 with respect to the light receiver 3 is adjusted by using the angle adjustment member 6 to enable the light receiver 3 to easily receive the light reflected from the object to be measured OB, for example, as compared with a case where the substrate 21 of the light emitter 2 is parallel to the light reception surface 32a of the light receiver 3.

Hereinafter, a relationship between the light emitter 2 and the light receiver 3 in the distance measurement apparatus 1 will be described in more detail with reference to FIG. 1. Each angle described in the present exemplary embodiment means an angle in a cross section of the distance measurement apparatus 1 cut along a plane perpendicular to the lateral direction SD in the semiconductor multilayer structure 10 of the light emitter 2.

As described above, the angle formed by the emission light Lf emitted from the semiconductor multilayer structure 10 of the light emitter 2 and the substrate 21 of the light emitter 2 is assumed as the emission angle θ1. Since the semiconductor multilayer structure 10 emits the light in the oblique direction inclined with respect to the substrate 21 and the normal line of the substrate 21, the emission angle θ1 is 0°<θ1<90°.

As described above, assuming that the angle formed by the substrate 21 of the light emitter 2 and the light reception surface 32a in the light reception sensor 32 of the light receiver 3 is the substrate angle 82, in the distance measurement apparatus 1 according to the present exemplary embodiment, the emission angle θ1 and the substrate angle 82 satisfy the following equation (1).

0°<θ2<180°−2θ1 (1)

In the distance measurement apparatus 1 according to the present exemplary embodiment, in a case where the emission angle θ1 and the substrate angle θ2 satisfy equation (1), an advancing direction of the light emitted from the semiconductor multilayer structure 10 is close to a direction perpendicular to the light reception surface 32a (upper-lower direction in FIG. 1), as compared with a case where equation (1) is not satisfied, for example, the substrate 21 of the light emitter 2 is parallel to the light reception surface 32a in the light reception sensor 32 of the light receiver 3 (that is, in a case where θ1=0°). Accordingly, in the distance measurement apparatus 1 according to the present exemplary embodiment, the light reception sensor 32 of the light receiver 3 easily receives the reflected light from the object to be measured OB, as compared with a case where the emission angle θ1 and the substrate angle θ2 do not satisfy equation (1).

In addition, in the distance measurement apparatus 1 according to the present exemplary embodiment, even in a case where the light-receiving viewing angle θr of the light reception sensor 32 is not larger than the diffusion angle θt of the diffusion plate 22 in the light emitter 2, the light reception sensor 32 of the light receiver 3 easily receives the reflected light from the object to be measured OB. Accordingly, the range that does not contribute to the reception of the reflected light within the range of the light-receiving viewing angle θr of the light reception sensor 32 is less likely to occur.

In the distance measurement apparatus 1, a sum of the emission angle θ1 and the substrate angle θ2 is, for example, preferably 90° (θ1+θ2=90°). With the sum of the emission angle θ1 and the substrate angle θ2 of 90°, the direction in which the light is emitted from the semiconductor multilayer structure 10 of the light emitter 2 and the direction perpendicular to the light reception surface 32a of the light reception sensor 32 are easier to match. Accordingly, the light reception sensor 32 more easily receives the reflected light emitted from the semiconductor multilayer structure 10 of the light emitter 2 and reflected by the object to be measured OB. In a case where the object to be measured OB is disposed in a vertical direction with respect to the light emitter 2, with the sum of the emission angle θ1 and the substrate angle θ2 of 90°, the light emitted from the semiconductor multilayer structure 10 of the light emitter 2 is likely to be evenly emitted with respect to the object to be measured OB. Accordingly, a measurement accuracy of the distance measurement apparatus 1 is improved.

The fact that the sum of the emission angle θ1 and the substrate angle θ2 is 90° (θ1+θ2=90°) means that all the light emitted from the semiconductor multilayer structure 10 does not need to strictly satisfy θ1+θ2=90° and at least a part of the light may be in a range in which the same result as the light at θ1+θ2=90° can be obtained. Even though the laser light has a strong straightness, the laser light spreads to some extent. Therefore, the direction of the light emitted from the semiconductor multilayer structure 10 changes also depending on the variation in the emission surface, the accuracy or variation of parts, and the like.

Further, in the distance measurement apparatus 1, the light emitter 2 is disposed so as to be away from the object to be measured OB as the substrate 21 and the semiconductor multilayer structure 10 loaded on the substrate 21 are closer to the anode wiring 41 and the cathode wiring 42, which are examples of a supply unit formed on the PCB board 4. In addition, in the light emitter 2, the anode wiring 211 and the cathode wiring 212 formed on the substrate 21 are respectively connected to the anode wiring 41 and the cathode wiring 42 of the PCB board 4 at a position farthest from the object to be measured OB on the substrate 21 (that is, position closest to the PCB board 4).

Accordingly, a connection path for connecting the anode wiring 211 and the cathode wiring 212 formed on the substrate 21 of the light emitter 2 and the anode wiring 41 and the cathode wiring 42 formed on the PCB board 4 can be shortened, which leads to miniaturization of the distance measurement apparatus 1.

In the distance measurement apparatus 1, the light receiver 3 is disposed on an opposite side (right side in FIG. 1) of the anode wiring 41 and the cathode wiring 42 formed on the PCB board 4 with respect to the light emitter 2. In this case, the light receiver 3 is less likely to interfere with the anode wiring 41 and the cathode wiring 42 on the PCB board 4, the power supply that supplies the electric power to the anode wiring 41 and the cathode wiring 42, or the like. Accordingly, as compared with a case where the light receiver 3 is disposed on the same side (left side in FIG. 1) as the anode wiring 41 and the cathode wiring 42 of the PCB board 4 with respect to the light emitter 2, the distance between the light emitter 2 and the light receiver 3 can be reduced, which leads to the miniaturization of the distance measurement apparatus 1.

### Second Exemplary Embodiment

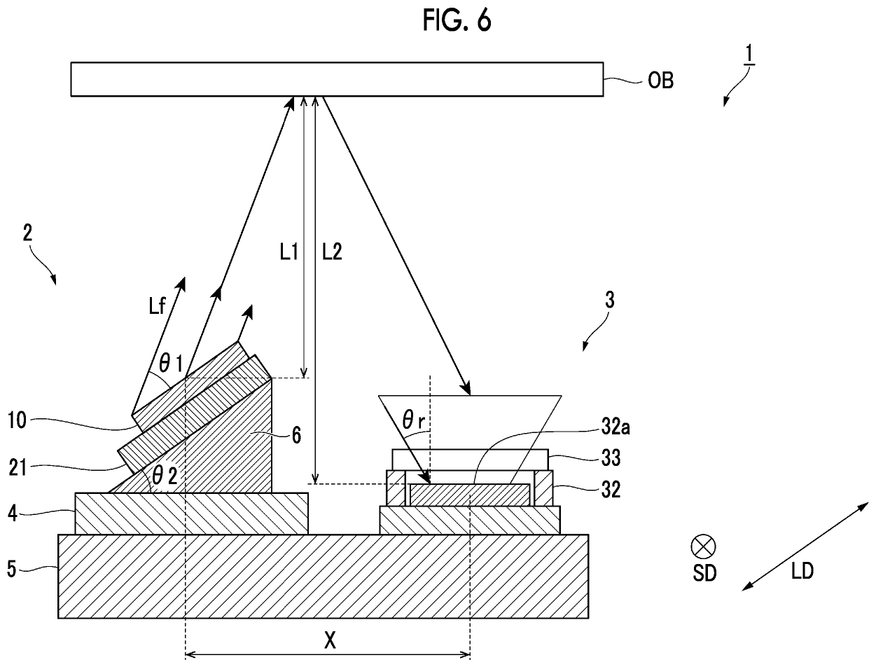

Subsequently, a second exemplary embodiment of the present invention will be described. FIG. 6 is a diagram showing an example of a configuration of the distance measurement apparatus 1 to which the second exemplary embodiment is applied, and, as in FIG. 1, corresponds to a diagram of the distance measurement apparatus 1 as viewed along the lateral direction SD of the semiconductor multilayer structure 10 in the light emitter 2. In FIG. 6, the description of the wiring and the like formed on the PCB board 4 and the substrate 21 is omitted. In the second exemplary embodiment, the same reference numerals are used for the same configurations as the configurations of the first exemplary embodiment, and a detailed description thereof will be omitted here.

In the distance measurement apparatus 1 according to the first exemplary embodiment described above, the emission light Lf emitted from the semiconductor multilayer structure 10 is diffused by the diffusion plate 22, the diffused light is emitted to the object to be measured OB to be measured, and the reflected light from the object to be measured OB to be measured is received by the light receiver 3.

On the contrary, the distance measurement apparatus 1 according to the second exemplary embodiment shown in FIG. 6 does not have the diffusion plate 22 (refer to FIG. 1) that diffuses the emission light Lf emitted from the semiconductor multilayer structure 10. In the distance measurement apparatus 1 according to the second exemplary embodiment, the emission light Lf emitted from the semiconductor multilayer structure 10 is directly emitted to the object to be measured OB, and the light receiver 3 receives the reflected light that is specularly reflected by the object to be measured OB.

In the distance measurement apparatus 1 according to the second exemplary embodiment, similarly to the first exemplary embodiment, the emission angle θ1 formed by the emission light Lf emitted from the semiconductor multilayer structure 10 and the substrate 21 and the substrate angle θ2 formed by the substrate 21 and the light reception surface 32a of the light reception sensor 32 satisfy equation (1) described above.

Accordingly, in the distance measurement apparatus 1 according to the second exemplary embodiment, the light reception sensor 32 of the light receiver 3 easily receives the reflected light from the object to be measured OB, as compared with a case where the emission angle θ1 and the substrate angle θ2 do not satisfy equation (1). In the distance measurement apparatus 1 according to the second exemplary embodiment, as compared with a case where the emission angle θ1 and the substrate angle θ2 do not satisfy equation (1), a distance between the light emitter 2 and the light receiver 3 (distance X described below, refer to FIG. 6) at which the reflected light is incident on the light reception sensor 32 of the light receiver 3 is shortened, which leads to the miniaturization of the distance measurement apparatus 1.

In the distance measurement apparatus 1 shown in FIG. 6, the sum (θ1+θ2) of the emission angle θ1 and the substrate angle θ2 is less than 90° (0°<θ1+θ2 <90°).

In this case, in the distance measurement apparatus 1, from the viewpoint of easily receiving the reflected light from the object to be measured OB by the light reception sensor 32 of the light receiver 3, the light receiver 3 is, for example, preferably disposed adjacent to a side of the light emitter 2 close to the object to be measured OB (right side in FIG. 6) with respect to the light emitter 2.

In the distance measurement apparatus 1 according to the second exemplary embodiment, in a relationship between the sum (θ1+θ2) of the emission angle θ1 and the substrate angle θ2 and the light-receiving viewing angle θr of the light receiver 3, the following equation (2) is, for example, preferably satisfied.

90°−θr<θ1+θ2<90° (2)

In a case where the sum of the emission angle θ1 and the substrate angle θ2 satisfies equation (2), the reflected light from the object to be measured OB easily enters the inside of the light-receiving viewing angle θr of the light receiver 3. Accordingly, the light reception sensor 32 of the light receiver 3 easily receives the reflected light from the object to be measured OB, as compared with a case where the sum of the emission angle θ1 and the substrate angle θ2 does not satisfy equation (2).

Assuming that a distance between the semiconductor multilayer structure 10 of the light emitter 2 and the object to be measured OB is a distance L1 and a distance between the light reception surface 32a of the light receiver 3 and the object to be measured OB is a distance L2, the distance X along the light reception surface 32a between the semiconductor multilayer structure 10 of the light emitter 2 and the light reception surface 32a of the light receiver 3, for example, preferably satisfies the following equation (3).

X=(L1+L2)×tan(θ1+θ2) (3)

In a case where the distance X satisfies equation (3), in the distance measurement apparatus 1 according to the second exemplary embodiment, the light reception surface 32a of the light reception sensor 32 is easily disposed in the advancing direction of the reflected light from the object to be measured OB. Accordingly, the light reception sensor 32 of the light receiver 3 easily receives the reflected light from the object to be measured OB, as compared with a case where the distance X does not satisfy equation (3).

The distance L1 is a distance along a direction perpendicular to the light reception surface 32a of the light receiver 3 between a center of the semiconductor multilayer structure 10 in the longitudinal direction LD (refer to FIG. 2) and the object to be measured OB (distance along upper-lower direction in FIG. 6). The distance L2 is a distance along a direction perpendicular to the light reception surface between a center of the light reception surface 32a and the object to be measured OB (distance along upper-lower direction in FIG. 6). Further, the distance X is a distance along the light reception surface 32a between the center of the semiconductor multilayer structure 10 and the center of the light reception surface 32a (distance along left-right direction in FIG. 6).

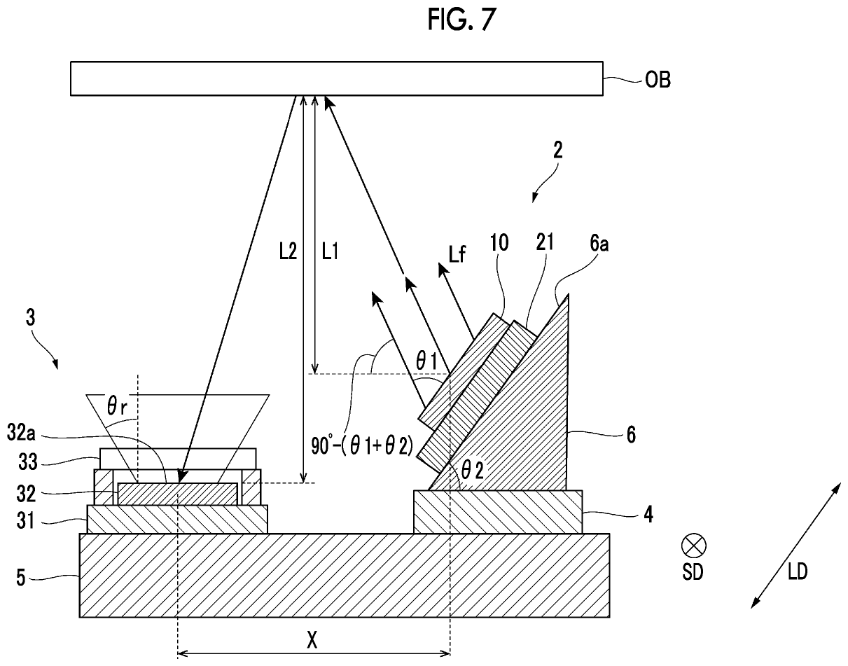

Subsequently, a modification example of the distance measurement apparatus 1 according to the second exemplary embodiment will be described. FIG. 7 is a diagram showing the modification example of the distance measurement apparatus 1 to which the second exemplary embodiment is applied, and, as in FIG. 6, is a diagram of the distance measurement apparatus 1 as viewed along the lateral direction SD of the semiconductor multilayer structure 10 in the light emitter 2. In FIG. 7, the same reference numerals are used for the same configurations as the configurations of the distance measurement apparatus 1 shown in FIG. 6.

In the distance measurement apparatus 1 shown in FIG. 6, the sum (θ1+θ2) of the emission angle θ1 and the substrate angle θ2 is less than 90°, whereas in the distance measurement apparatus 1 of the modification example shown in FIG. 7, the sum (θ1+θ2) of the emission angle θ1 and the substrate angle θ2 is 90° or more and less than 180° (90°≤θ1+θ<80°).

In the distance measurement apparatus 1 shown in FIG. 7, from the viewpoint of easily receiving the reflected light from the object to be measured OB by the light reception sensor 32 of the light receiver 3, the light receiver 3 is, for example, preferably disposed adjacent to a side of the light emitter 2 far from the object to be measured OB (left side in FIG. 7) with respect to the light emitter 2.

Also in the distance measurement apparatus 1 shown in FIG. 7, the emission angle θ1 formed by the emission light Lf emitted from the semiconductor multilayer structure 10 and the substrate 21 and the substrate angle θ2 formed by the substrate 21 and the light reception surface 32a of the light reception sensor 32 satisfy equation (1) described above.

Accordingly, in the distance measurement apparatus 1 according to the second exemplary embodiment, the light reception sensor 32 of the light receiver 3 easily receives the reflected light from the object to be measured OB, as compared with a case where the emission angle θ1 and the substrate angle θ2 do not satisfy equation (1).

In the distance measurement apparatus 1 shown in FIG. 7, in a relationship between the sum (θ1+θ2) of the emission angle θ1 and the substrate angle θ2 and the light-receiving viewing angle er of the light receiver 3, the following equation (4) is, for example, preferably satisfied.

90°≤θ1+θ2<90°+θr (4)

In a case where the sum of the emission angle θ1 and the substrate angle θ2 satisfies equation (4), the reflected light from the object to be measured OB easily enters the inside of the light-receiving viewing angle er of the light receiver 3. Accordingly, the light reception sensor 32 of the light receiver 3 easily receives the reflected light from the object to be measured OB, as compared with a case where the sum of the emission angle θ1 and the substrate angle θ2 does not satisfy equation (4).

As in the example shown in FIG. 6, assuming that a distance between the semiconductor multilayer structure 10 of the light emitter 2 and the object to be measured OB is a distance L1 and a distance between the light reception surface 32a of the light receiver 3 and the object to be measured OB is a distance L2, the distance X along the light reception surface 32a between the semiconductor multilayer structure 10 of the light emitter 2 and the light reception surface 32a of the light receiver 3, for example, preferably satisfies equation (3) described above.

In a case where the distance X satisfies equation (3), the light reception surface 32a of the light reception sensor 32 is easily disposed in the advancing direction of the reflected light from the object to be measured OB also in the distance measurement apparatus 1 shown in FIG. 7. Accordingly, the light reception sensor 32 of the light receiver 3 easily receives the reflected light from the object to be measured OB, as compared with a case where the distance X does not satisfy equation (3).

As described above, as in the distance measurement apparatus 1 shown in FIGS. 6 and 7, even in a case where the light emitter 2 does not include the diffusion plate 22 (refer to FIG. 1) and the light receiver 3 receives the reflected light that is emitted from the light emitter 2 and is specularly reflected by the object to be measured OB, equation (1) described above is satisfied. Therefore, the light reception sensor 32 of the light receiver 3 easily receives the reflected light from the object to be measured OB.

Further, in the distance measurement apparatus 1 shown in FIGS. 6 and 7, in a case where the relationships, shown in equations (2) and (4) described above, between the sum (θ1+θ2) of the emission angle θ1 and the substrate angle θ2 and the light-receiving viewing angle θr of the light receiver 3 are summarized, the following equation (5) is, for example, preferably satisfied.

90°−θr<θ1+θ2<90°+θr (5)

In the distance measurement apparatus 1, in a case where equation (5) is satisfied, the light reception sensor 32 of the light receiver 3 easily receives the reflected light from the object to be measured OB, as compared with a case where equation (5) is not satisfied.

### Third Exemplary Embodiment

By the way, in the distance measurement apparatus 1, in a case where the semiconductor multilayer structure 10 having the longitudinal direction LD is used to emit the light to the object to be measured OB, there may be a difference in an optical path length, between one end and the other end of the semiconductor multilayer structure 10 in the longitudinal direction LD, until the light emitted from the semiconductor multilayer structure 10 reaches the object to be measured OB. In addition, in the distance measurement apparatus 1, there may be a difference in a time, between one end and the other end of the semiconductor multilayer structure 10 in the longitudinal direction LD, until the light emitted from the semiconductor multilayer structure 10 reaches the object to be measured OB. In this case, there may be an error in an output result of the light reception sensor 32 that receives the reflected light from the object to be measured OB.

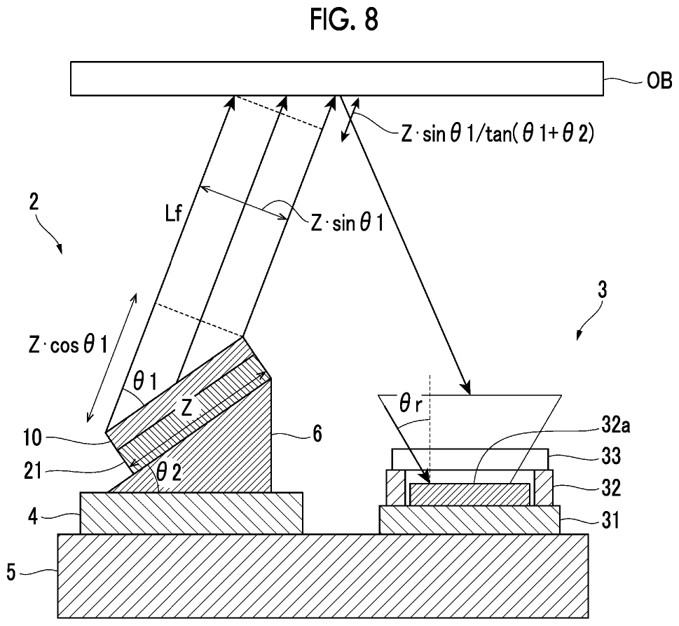

FIG. 8 is a diagram for describing the optical path length and the like until the light emitted from the semiconductor multilayer structure 10 reaches the object to be measured OB in the distance measurement apparatus 1. The distance measurement apparatus 1 shown in FIG. 8 has the same configuration as the distance measurement apparatus 1 shown in FIG. 6.

As shown in FIG. 8, in the distance measurement apparatus 1, assuming that a length of the semiconductor multilayer structure 10 along the longitudinal direction LD is Z, a difference Δd1 in the optical path length until the light emitted from one end (left side in FIG. 8) and the other end (right side in FIG. 8) of the semiconductor multilayer structure 10 in the longitudinal direction LD reaches the object to be measured OB is expressed by the following equation (6).

Δd1=Z×cos θ1−Z×sin θ1/tan(θ1+θ2) (6)

The time difference until the light emitted from one end and the other end of the semiconductor multilayer structure 10 in the longitudinal direction LD reaches the object to be measured OB is expressed as Δd1/c, where c is the speed of light.

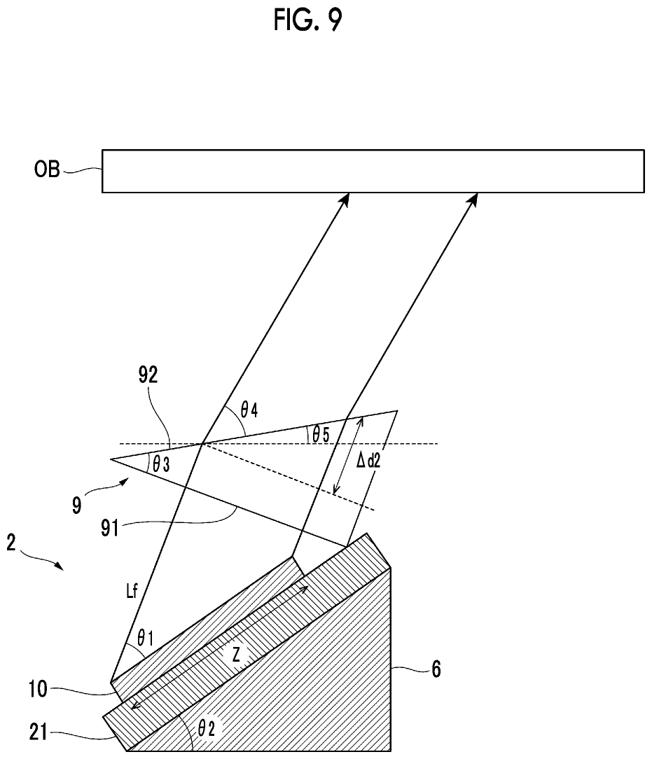

FIG. 9 is a diagram for describing a configuration of the distance measurement apparatus 1 (refer to FIG. 8) to which the third exemplary embodiment is applied, and is a diagram showing the configuration between the light emitter 2 and the object to be measured OB.

In the distance measurement apparatus 1 according to the third exemplary embodiment, from the viewpoint of reducing the time difference Δd1/c until the light emitted from one end and the other end of the semiconductor multilayer structure 10 in the longitudinal direction LD reaches the object to be measured OB, a prism 9 which is an example of a light adjustment unit is provided between the light emitter 2 and the object to be measured OB.

Specifically, as shown in FIG. 9, the prism 9 includes an incident surface 91 that faces the semiconductor multilayer structure 10 and is incident with the light emitted from the semiconductor multilayer structure 10 and an emission surface 92 that forms an inclination angle θ3 (0°<θ3 <90°) set in advance with respect to the incident surface 91 and emits light passing through the prism 9. In addition, as shown in FIG. 9, the prism 9 has a triangular cross-sectional shape on a plane of the semiconductor multilayer structure 10 perpendicular to the lateral direction SD.

In the distance measurement apparatus 1 according to the present exemplary embodiment, the prism 9 is disposed such that the emission light Lf emitted from the semiconductor multilayer structure 10 is perpendicularly incident on the incident surface 91.

A difference in the optical path length in which the light emitted from one end and the other end of the semiconductor multilayer structure 10 in the longitudinal direction LD and entering the prism 9 advances in the prism 9 (difference in optical path length from the incident surface 91 to the emission surface 92) Δd2 is expressed by the following equation (7).

Δd2=Z×sin θ1×tan θ3 (7)

A speed of the light advancing in the prism 9 is c/n, where n is the refractive index of the prism 9. Therefore, a time difference until the light emitted from one end and the other end of the semiconductor multilayer structure 10 in the longitudinal direction LD and entering the prism 9 reaches the emission surface 92 from the incident surface 91 is expressed as Δd2×n/c.

In the present exemplary embodiment, a shape of the prism 9 (angle Θ3 formed by the incident surface 91 and the emission surface 92 of the prism 9) and the refractive index n of the prism 9 are, for example, preferably determined such that Δd1=Δd2×n.

Accordingly, in the distance measurement apparatus 1, the optical path length difference and the time difference until the light emitted from one end and the other end of the semiconductor multilayer structure 10 in the longitudinal direction LD reaches the object to be measured OB are reduced, and thus the error in an output result of the light reception sensor 32 that receives the reflected light from the object to be measured OB is less likely to occur.

In the distance measurement apparatus 1, even in a case where the prism 9 satisfying Δd1=Δd2×n described above is disposed between the semiconductor multilayer structure 10 and the object to be measured OB, the optical path length difference and the time difference until the light emitted from one end and the other end of the semiconductor multilayer structure 10 in the longitudinal direction LD reaches the object to be measured OB may remain. Although a detailed calculation is omitted, from the viewpoint of more reducing the optical path length difference and the time difference until the light emitted from one end and the other end of the semiconductor multilayer structure 10 in the longitudinal direction LD reaches the object to be measured OB, for example, selection of the prism 9 satisfying the following equation (8) is more preferable.

Z×cos θ1+Δd2×cos θ4/sin θ3=Δd2×n+Δd2×sin θ4/{sin θ3×tan(θ4+θ5)} (8)

In equation (8), an angle θ4 is formed by the emission surface 92 of the prism 9 and the light refracted by the prism 9 and emitted from the prism 9. In equation (8), an angle θ5 is formed by the light reception surface 32a of the light receiver 3 (both refer to FIG. 6) and the emission surface 92 of the prism 9.

In the third exemplary embodiment, the distance measurement apparatus 1 has been described as an example in which the emission light Lf emitted from the semiconductor multilayer structure 10 is directly emitted to the object to be measured OB, and the light receiver 3 receives the reflected light that is specularly reflected by the object to be measured OB. However, the present invention is not limited thereto. The prism 9 according to the third exemplary embodiment may be applied to a distance measurement apparatus 1 provided with the light emitter 2 including the diffusion plate 22. In this case, for example, the prism 9 may be provided between the semiconductor multilayer structure 10 of the light emitter 2 and the diffusion plate 22.

In the third exemplary embodiment, the prism 9 having the triangular cross-sectional shape is used as an example of an optical path length adjustment unit that reduces the optical path length difference until the light emitted from one end and the other end of the semiconductor multilayer structure 10 in the longitudinal direction LD reaches the object to be measured OB. However, the prism 9 having a different shape may be used, or an optical component other than the prism 9 may be used. The optical path length adjustment unit may be formed by combining a plurality of optical components and the like.

### Fourth Exemplary Embodiment

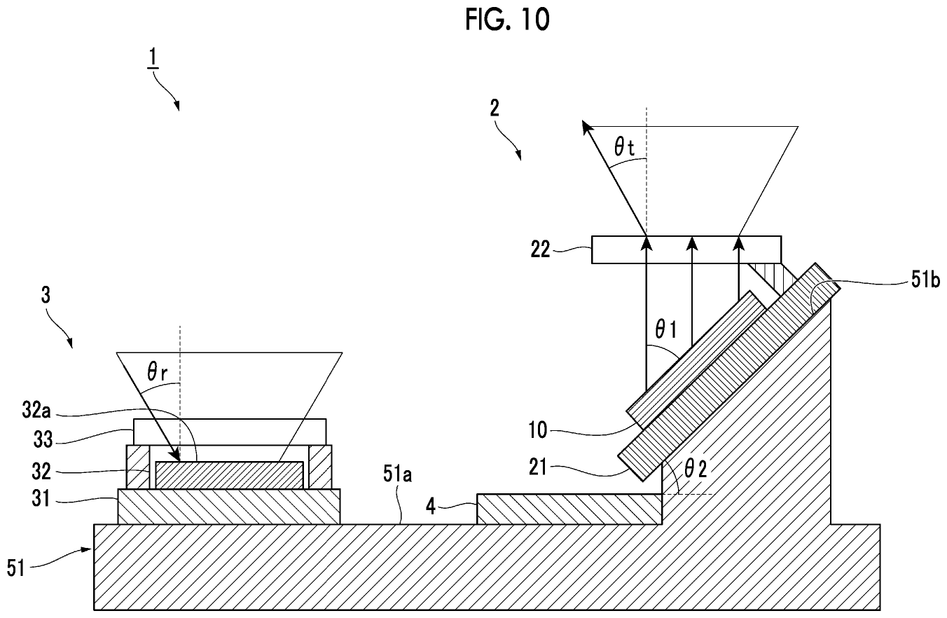

Subsequently, a fourth exemplary embodiment of the present invention will be described. FIG. 10 is a diagram showing an example of a configuration of the distance measurement apparatus 1 to which the fourth exemplary embodiment is applied, and, as in FIG. 1, corresponds to a diagram of the distance measurement apparatus 1 as viewed along the lateral direction SD of the semiconductor multilayer structure 10 in the light emitter 2. In FIG. 10, the description of the wiring and the like formed on the PCB board 4 and the substrate 21 is omitted. In FIG. 10, although the description of the object to be measured OB (refer to FIG. 1) is omitted, the object to be measured OB is disposed at an upper part of the figure with respect to the distance measurement apparatus 1 as in FIG. 1. Further, in the fourth exemplary embodiment, the same reference numerals are used for the same configurations as the configurations of the first exemplary embodiment, and a detailed description thereof will be omitted here.

In the first exemplary embodiment described above, the PCB board 4 is loaded on the pedestal 5, and the angle adjustment member 6 (refer to FIG. 1) is provided on the PCB board 4. As a result, the substrate 21 of the light emitter 2 and the light reception surface 32a in the light reception sensor 32 of the light receiver 3 form the substrate angle θ2.

On the contrary, in the distance measurement apparatus 1 according to the fourth exemplary embodiment, the pedestal 51 is included as an example of a support member that supports the light emitter 2 such that the substrate 21 of the light emitter 2 and the light reception surface 32a of the light receiver 3 form the substrate angle θ2, and the light receiver 3 is supported by the pedestal 51 together with the light emitter 2.

Specifically, as shown in FIG. 10, the pedestal 51 includes a flat surface 51a parallel to the light reception surface 32a in the light reception sensor 32 and an inclined surface 51b that projects from the flat surface 51a toward the object to be measured OB and forms an angle set in advance (substrate angle θ2) with respect to the flat surface 51a. In the distance measurement apparatus 1 according to the fourth exemplary embodiment, the light receiver 3 is loaded on the flat surface 51a, and the substrate 21 of the light emitter 2 is loaded on the inclined surface 51b. As a result, the substrate 21 and the light reception surface 32a in the light reception sensor 32 of the light receiver 3 form the substrate angle θ2.

As described above, in the distance measurement apparatus 1 according to the fourth exemplary embodiment, the light emitter 2 and the light receiver 3 are supported by the common pedestal 51. As a result, the number of alignments for adjusting the light emitter 2 and the light receiver 3 to have a positional relationship set in advance is reduced. Accordingly, a positional accuracy between the light emitter 2 and the light receiver 3 is improved, and the light receiver 3 easily receives the reflected light emitted from the light emitter 2 and reflected by the object to be measured OB.

In the distance measurement apparatus 1 shown in FIG. 10, the light emitter 2 is disposed such that the substrate 21 and the semiconductor multilayer structure 10 loaded on the substrate 21 are closer to the object to be measured OB as the substrate 21 and the semiconductor multilayer structure 10 are farther from the light receiver 3. In other words, in the distance measurement apparatus 1 shown in FIG. 10, the light receiver 3 is disposed adjacent to a side of the light emitter 2 far from the object to be measured OB (left side in FIG. 10) with respect to the light emitter 2.

With such a configuration, the reflected light from the object to be measured OB is prevented from being blocked by the inclined surface 51b or the like on which the light emitter 2 or the substrate 21 of the light emitter 2 is loaded. Further, a shadow is prevented from being formed on the light reception surface 32a of the light receiver 3 due to the inclined surface 51b or the like on which the light emitter 2 or the substrate 21 of the light emitter 2 is loaded.

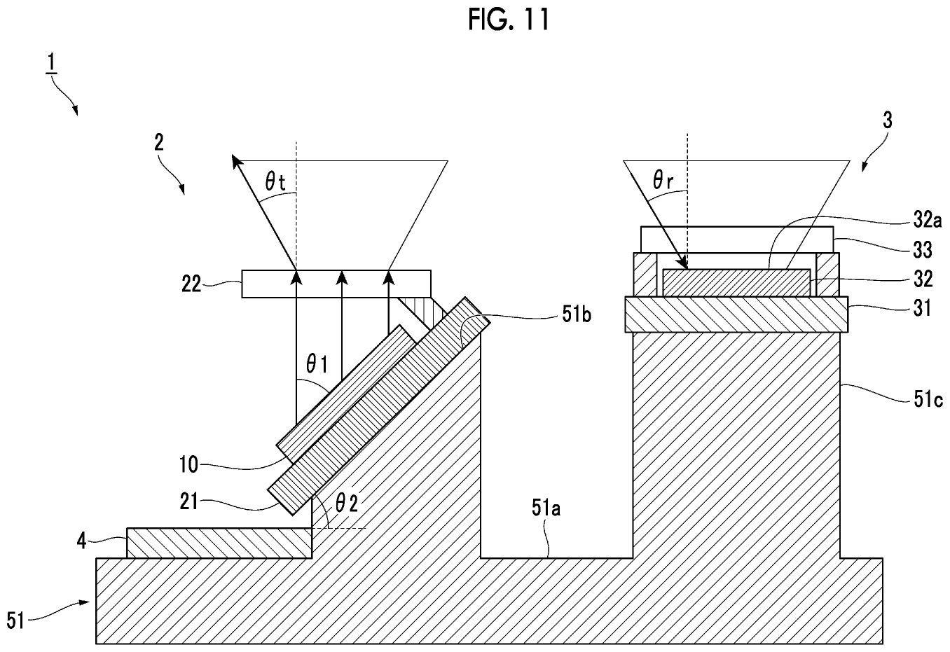

Subsequently, a modification example of the distance measurement apparatus 1 according to the fourth exemplary embodiment will be described. FIG. 11 is a diagram showing a modification example of the distance measurement apparatus 1 to which the fourth exemplary embodiment is applied, and, as in FIG. 10, is a diagram of the distance measurement apparatus 1 as viewed along the lateral direction SD of the semiconductor multilayer structure 10 in the light emitter 2. In FIG. 11, the same reference numerals are used for the same configurations as the configurations of the distance measurement apparatus 1 shown in FIG. 10. In FIG. 11, although the description of the object to be measured OB (refer to FIG. 1) is omitted, the object to be measured OB is disposed at an upper part of the figure with respect to the distance measurement apparatus 1 as in FIG. 1.

In the distance measurement apparatus 1 shown in FIG. 11, the pedestal 51 includes the inclined surface 51b that projects from the flat surface 51a toward the object to be measured OB and forms the angle set in advance (substrate angle θ2) with respect to the flat surface 51a, as in the distance measurement apparatus 1 shown in FIG. 10. In the distance measurement apparatus 1 shown in FIG. 11, the substrate 21 of the light emitter 2 is loaded on the inclined surface 51b of the pedestal 5. As a result, the light emitter 2 and the light receiver 3 are both supported by the pedestal 51.

Accordingly, also in the distance measurement apparatus 1 shown in FIG. 11, the number of alignments for adjusting the light emitter 2 and the light receiver 3 to have a positional relationship set in advance is reduced. An alignment accuracy between the light emitter 2 and the light receiver 3 is improved, and the light receiver 3 easily receives the reflected light emitted from the light emitter 2 and reflected by the object to be measured OB.

In the distance measurement apparatus 1 shown in FIG. 11, the pedestal 51 includes a projection portion 51c that projects from the flat surface 51a toward the object to be measured OB and has an upper surface, which is closest to the object to be measured OB, formed in parallel with the flat surface 51a. In the distance measurement apparatus 1 shown in FIG. 11, the light receiver 3 is loaded on the projection portion 51c of the pedestal 51.

Accordingly, in the distance measurement apparatus 1 shown in FIG. 11, the light receiver 3 is provided at a position closer to the object to be measured OB than the light emitter 2. In this example, the light reception surface 32a of the light receiver 3 is provided at a position closer to the object to be measured OB than the semiconductor multilayer structure 10 of the light emitter 2. With such a configuration, the reflected light from the object to be measured OB is prevented from being blocked by the inclined surface 51b or the like on which the light emitter 2 or the substrate 21 of the light emitter 2 is loaded. Further, a shadow is prevented from being formed on the light reception surface 32a of the light receiver 3 due to the inclined surface 51b or the like on which the light emitter 2 or the substrate 21 of the light emitter 2 is loaded.

### Fifth Exemplary Embodiment

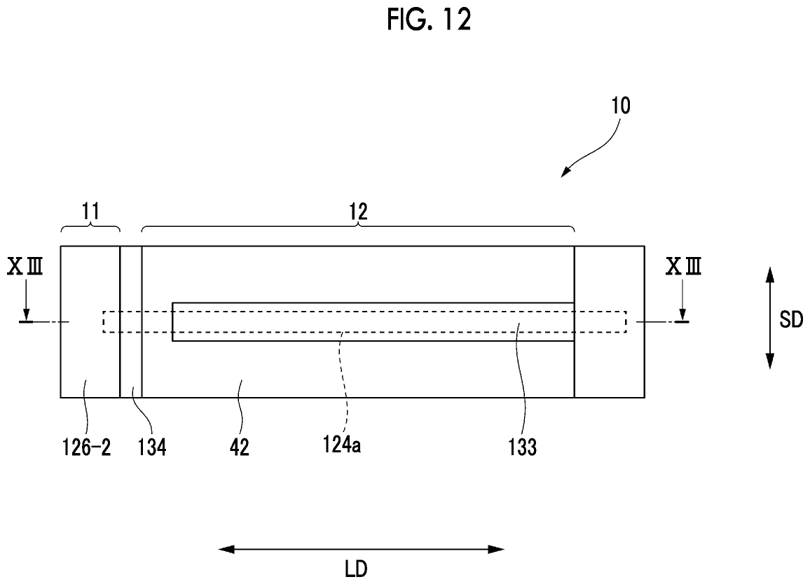

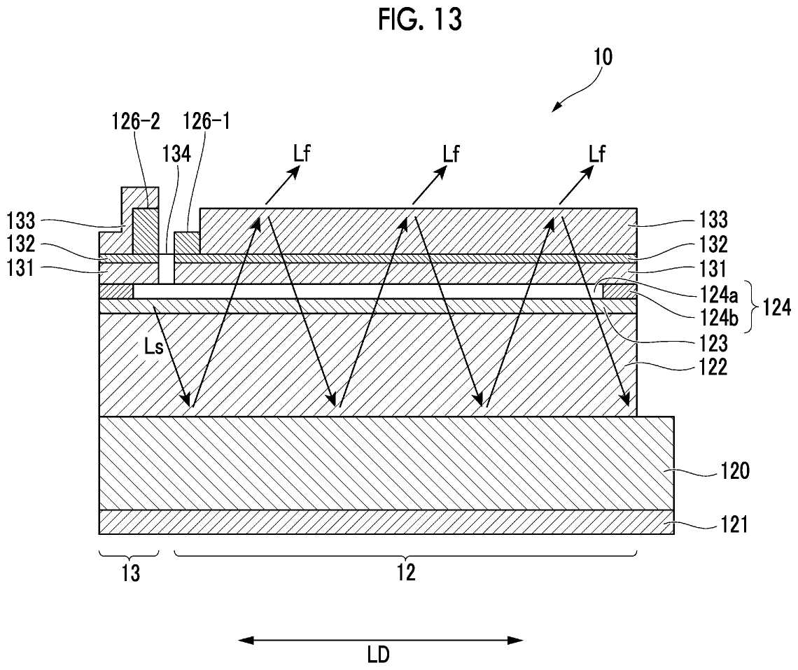

Subsequently, another form of the semiconductor multilayer structure 10 in the light emitter 2 will be described. FIGS. 12 and 13 are views of configurations of the semiconductor multilayer structure 10 to which the fifth exemplary embodiment is applied. FIG. 12 is a plan view of the semiconductor multilayer structure 10 to which the fifth exemplary embodiment is applied, and FIG. 13 is a cross-sectional view taken along a line XIII-XIII shown in FIG. 12.

The semiconductor multilayer structure 10 according to the fifth exemplary embodiment is a form in which, for example, a light emitting element such as a VCSEL is integrally formed in a region where the optical coupling portion 11 of the semiconductor multilayer structure 10 according to the first exemplary embodiment is disposed. The same reference numerals are used for the same configurations as the configurations of the semiconductor multilayer structure 10 according to the first exemplary embodiment, and a detailed description thereof will be omitted.

As shown in FIGS. 12 and 13, the semiconductor multilayer structure 10 is divided into a seed light unit 13 and the light amplification unit 12. As shown in FIG. 13, the semiconductor multilayer structure 10 includes the lower DBR layer 122, the active layer 123, the oxidization constriction layer 124, a p-DBR layer 131, a phase control layer 132, an i-DBR layer 133, an insulation portion 134, and P electrodes 126-1 and 126-2, which are stacked on a front surface of the base layer 120, and the N electrode 121 stacked on the back surface of the base layer 120.

The seed light unit 13 is a portion that generates the seed light Ls and is configured as the VCSEL in the present exemplary embodiment. As shown in FIG. 13, the seed light Ls generated from the seed light unit 13 propagates toward the light amplification unit 12.

The p-DBR layer 131 and the i-DBR layer 133 are layers corresponding to the upper DBR layer 125 in the semiconductor multilayer structure 10 according to the first exemplary embodiment. The p-DBR layer 131 is a p-type containing a p-type impurity, and the i-DBR layer 133 does not contain an impurity.

The phase control layer 132 is formed between the p-DBR layer 131 and the i-DBR layer 133 and is a layer that adjusts a relationship between a wavelength of the seed light Ls and a perpendicular resonance wavelength in the light amplification unit 12. In the present exemplary embodiment, the phase control layer 132 is formed by using, for example, a silicon oxide film (SiO₂), a silicon nitride film (SiON), or GaAs. In the present exemplary embodiment, the wavelength of the seed light Ls is controlled by etching the phase control layer 132 after the formation thereof to reduce a film thickness of the phase control layer 132, as an example.

The insulation portion 134 is a layer that electrically insulates the seed light unit 13 from the light amplification unit 12 and is formed by ion implantation, as an example, in the present exemplary embodiment.

The P electrode 126-1 is a P electrode of the light amplification unit 12, and the P electrode 126-2 is a P electrode of the seed light unit 13.

The semiconductor multilayer structure 10 according to the present exemplary embodiment having the above configuration is a form in which the light source of the seed light Ls is integrated into the structure in the semiconductor multilayer structure 10 according to the first exemplary embodiment. The semiconductor multilayer structure 10 according to the present exemplary embodiment has the same functions and actions as the semiconductor multilayer structure 10 according to the first exemplary embodiment. With the semiconductor multilayer structure 10 according to the present exemplary embodiment, an additional light source is not required except for the semiconductor multilayer structure 10, and thus the function of the light emission unit that emits the light in the light emitter 2 is realized by one chip.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A measurement apparatus comprising:
a light emitter including a substrate and a light emission unit that emits light in an inclined direction inclined with respect to the substrate and a normal line of the substrate; and
a light receiver that receives, on a light reception surface, reflected light emitted from the light emitter and reflected by an object to be measured,
wherein in a case where an angle formed by the light emitted from the light emitter and the substrate of the light emitter is an angle θ1 (0°<θ1<90°), an angle θ2 formed by the substrate and the light reception surface of the light receiver satisfies 0°<θ2<180°−2θ1.

2. The measurement apparatus according to claim 1,
wherein the light emitter further includes a diffusion plate that is provided between the light emission unit and the object to be measured and diffuses and transmits the light emitted from the light emission unit toward the object to be measured.

3. The measurement apparatus according to claim 1,
wherein the angle θ1 and the angle θ2 satisfy θ1+θ2=90°.

4. The measurement apparatus according to claim 2,
wherein the angle θ1 and the angle θ2 satisfy θ1+θ2=90°.

5. The measurement apparatus according to claim 1,
wherein the light emitter is disposed so as to be closer to the object to be measured as the light emitter is farther from the light receiver.

6. The measurement apparatus according to claim 2,
wherein the light emitter is disposed so as to be closer to the object to be measured as the light emitter is farther from the light receiver.

7. The measurement apparatus according to claim 3,
wherein the light emitter is disposed so as to be closer to the object to be measured as the light emitter is farther from the light receiver.

8. The measurement apparatus according to claim 4,
wherein the light emitter is disposed so as to be closer to the object to be measured as the light emitter is farther from the light receiver.

9. The measurement apparatus according to claim 1,
wherein the light receiver receives the reflected light emitted from the light emitter and specularly reflected by the object to be measured.

10. The measurement apparatus according to claim 9,
wherein in a case where a viewing angle of the light receiver is θr, the angle θ1 and the angle θ2 satisfy 90°−θr<θ1+θ2<90°+θr.

11. The measurement apparatus according to claim 10,
wherein in a case where a distance between the light emitter and the object to be measured is L1 and a distance between the light receiver and the object to be measured is L2,
a distance X between the light emission unit of the light emitter and the light receiver along the light reception surface satisfies X=(L1+L2)×tan (θ1+θ2).

12. The measurement apparatus according to claim 1,
wherein the light emission unit of the light emitter extends in a longitudinal direction along the substrate, is disposed so as to approach the object to be measured from one end to the other end in the longitudinal direction, and emits the light in the inclined direction inclined in the longitudinal direction, and
the measurement apparatus further comprises a light adjustment unit that is provided between the light emission unit of the light emitter and the object to be measured and reduces an optical path length difference or a time difference until the light emitted from the one end and the other end of the light emission unit in the longitudinal direction reaches the object to be measured.

13. The measurement apparatus according to claim 1,
wherein the light receiver is provided at a position closer to the object to be measured than the light emitter.

14. The measurement apparatus according to claim 1, further comprising:
a support member that supports the light emitter such that the substrate of the light emitter and the light reception surface of the light receiver form the angle θ2,
wherein the light receiver is supported by the support member together with the light emitter.

15. The measurement apparatus according to claim 1, further comprising:
a supply unit that supplies electric power to the light emission unit of the light emitter,
wherein the light emitter is farther from the object to be measured as the light emitter is closer to the supply unit.

16. The measurement apparatus according to claim 15,
wherein the light receiver is disposed on an opposite side of the supply unit with respect to the light emitter.
